(19) United States
(12) Patent Application Publication
(10) Pub. No.: US 2015/0371828 A1
(43) Pub. Date: Dec. 24, 2015

(54) LOW COST WIDE PROCESS RANGE MICROWAVE REMOTE PLASMA SOURCE WITH MULTIPLE EMITTERS

(71) Applicant: APPLIED MATERIALS, INC., Santa Clara, CA (US)

(72) Inventor: Michael W. Stowell, Loveland, CO (US)

(21) Appl. No.: 14/313,173

(22) Filed: Jun. 24, 2014

(51) Int. Cl. H01J 37/32; C23C 16/455; C23C 16/511

(52) U.S. Cl. CPC H01J 37/32192; C23C 16/511; C23C 16/45559; C23C 16/45591; H01J 37/32394; H01J 37/32449; H01J 37/32633

(57) ABSTRACT

A remote plasma source has an array of low cost microwave magnetron heads coupled to individual conical, horn or other microwave emitter antennas above a gas shower head of a workpiece processing chamber.

### BACKGROUND

1. Technical Field

The disclosure relates to processing a workpiece, such as a semiconductor wafer, or cleaning a workpiece processing chamber.

2. Background Discussion

In etch and chemical vapor deposition (CVD) processes, reactive gases are supplied to the workpiece surface where reactions take place to etch an existing film (in etch processes) or form a desired film (in CVD processes) over the surface of the substrate being processed. In such processes, a plasma is formed using radio frequency (RF) energy or microwave energy to decompose and/or energize reactive species in reactant gases to produce the desired reactions.

One problem that arises during such plasma processes is that unwanted deposition of a residue occurs in the processing chamber and leads to potentially high maintenance costs. Undesired film or residue deposition can occur on any hot surface including the heater and/or various components of the process chamber, such as process kit parts for example. The undesired film grows during processing of successive workpieces, which degrades process performance, necessitating replacement of the various components of the process chamber, increasing the cost of operating the processing chamber.

A reactive plasma cleaning procedure is regularly performed in situ (in the processing chamber) to remove the unwanted deposition material from the chamber walls, heater, and other process kit parts of the processing chamber. Commonly performed between process steps for every wafer or a predetermined number of wafers, this in situ cleaning procedure is performed by dissociation of an etching (etchant precursor) gas through application of RF energy. However, where the residue to be removed contains a metal (e.g., a metal silicide), etching gases useful for etching the unwanted residue are often corrosive and attack the materials which make up the chamber, heater, and process kit parts of the processing chamber. Moreover, the in situ plasma cleaning procedure also causes ion bombardment of the metallic parts of the processing chamber. The ion bombardment makes it difficult to effectively clean the residue without damaging the heater and other chamber parts in the cleaning process, thus reducing the operational life of these components.

In order to overcome the problem of damaging chamber components during cleaning, one conventional approach employs a remote plasma source (RPS). The RPS provides radical species for cleaning the workpiece processing chamber. In a conventional RPS, the process pressure range is limited to relatively high pressures, leading to loss of radical species through recombination. This limits the concentration of radical species delivered to the processing chamber, thereby limiting throughput. With a conventional RPS cleaning system, the radicals generated in the RPS are delivered through a delivery tube into the volume above the gas shower head. Radicals recombine (are lost) within the RPS, the delivery tube and gas shower head, which limits the radical population delivered to the process.

A conventional RPS has limited performance in part due to the limited pressure range (e.g., 2-6 Torr) required for its efficient operation. This relatively high pressure range limits the density of the radical species delivered to the process, and promotes the recombination of radical species within the RPS, the delivery tube and the gas showerhead. Such recombination can reduce the radical species population delivered to the main chamber by a factor of a thousand, depending upon the type of radical species.

As an alternative to in situ plasma cleaning, some conventional plasma processing systems have their workpiece processing chamber connected through a delivery tube to a separate microwave RPS chamber having a microwave plasma source, which may be referred to as a microwave RPS. A microwave RPS is very expensive and therefore undesirable for many applications. The desired radical species are obtained as by-products from the plasma in the separate microwave RPS chamber. However, the microwave RPS suffers to a lesser degree some of the drawbacks of a conventional RPS plasma cleaning system. For example, as radical species flow from the separate microwave RPS chamber to the workpiece processing chamber, radical species recombine (are lost) within the RPS, the delivery tube and the gas shower head, which limits the radical population delivered to the process. Some of the radicals from the remote plasma may react with the components of the chamber. This may cause physical damage to the components of the chamber, including the chamber walls, substantially reducing their operational life. In addition, reactions between the chamber components and the radicals leaves a residue on the chamber components which may contaminate wafer surfaces during processing.

### SUMMARY

A plasma reactor having a microwave remote plasma source comprises chamber comprising a side wall and a ceiling, and a workpiece support stage within the chamber, an array of plural microwave sources mounted on an external side of the ceiling and an ion-blocking baffle between the ceiling and the workpiece support stage and defining: (a) an upper chamber portion between the ceiling and the ion-blocking baffle and (b) a lower chamber portion between the workpiece support stage and the ion-blocking baffle. The reactor further comprises a gas distributor comprising gas injection ports open to the upper chamber portion, and a process gas supply coupled to the gas distributor.

In one embodiment, each one of the microwave sources comprises a magnetron and a conical radiator antenna, each hollow conical radiator antenna having a cone apex facing the magnetron and a cone base facing the external surface of the ceiling.

The ceiling comprises a dielectric material. In one embodiment, the ceiling comprises a disk-shaped dielectric plate. In another embodiment, the ceiling comprises a metal plate, the metal plate comprising an array of plural openings extending through the metal plate in registration with respective ones of the plural microwave sources, and dielectric windows within the plural openings. In one implementation, each of the plural openings is circular with a diameter corresponding to a diameter of a respective conical base of the conical radiator antenna.

In one embodiment, the gas distributor is comprised within the ion-blocking baffle. In another embodiment, the gas distributor comprises gas injection ports in the side wall adjacent the upper chamber portion.

In one embodiment, each of the microwave sources occupies a zone of the ceiling that is sufficiently small that the array of microwave sources fits within a circumference of the ceiling.

In one embodiment, the plural microwave sources are spaced apart from one another at uniform intervals.

In one embodiment, the ceiling is planar and the plural microwave sources are attached to the ceiling and are arrayed in a plane.

In one embodiment, each hollow conical radiator antenna has an axis of symmetry parallel with an axis of symmetry of the ceiling.

In an embodiment, the ion-blocking baffle comprises an array of slots extending from the upper chamber portion to the lower chamber portion, each of the slots being sufficiently narrow to limit or prevent propagation of plasma ions through the slots. The slots are sufficiently wide to permit diffusion of neutral radical species through the ion-blocking baffle. In one embodiment, the ion-blocking baffle comprises metal.

A vacuum pump is coupled to the lower chamber portion. The process gas supply contains gas comprising a precursor of a desired radical species.

In accordance with another aspect, a method is provided of treating with radical species either a surface of a workpiece in a process chamber or an internal surface of the process chamber. The method comprises forming a ceiling of the process chamber of a material comprising a dielectric material, dividing the process chamber into an upper portion and a lower portion, mounting an array of plural microwave sources on an external side of the ceiling, injecting a process gas into the upper portion, and generating a plasma in the upper portion by radiating microwave power from the array of plural microwave sources into the upper portion of the process chamber, while preventing plasma ions from passing into the lower portion, and while allowing radical species to flow from the upper portion into the lower portion.

The microwave power may be of a frequency of about 2.45 GHz. The chamber may be maintained at pressure of less than 2 Torr.

### BRIEF DESCRIPTION OF THE DRAWINGS

So that the manner in which the exemplary embodiments of the present invention are attained can be understood in detail, a more particular description of the invention summarized above is given by reference to the embodiments thereof which are illustrated in the appended drawings. It is to be appreciated that certain well known processes are not discussed herein in order to not obscure the invention.

FIG. 1 is a simplified cut-away elevational view of a plasma reactor in accordance with a first embodiment.

FIG. 1A depicts one implementation of a gas shower head in the embodiment of FIG. 1.

FIG. 1B depicts an embodiment employing a mesh in place of the gas shower head.

FIG. 2 is a plan view corresponding to FIG. 1.

FIG. 3 is an enlarged elevational cut-away view of a microwave source in the embodiment of FIG. 1.

FIG. 4 is a plan view of a support plate in accordance with a further embodiment.

FIG. 5 is a partially cut-away elevational view corresponding to FIG. 4.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

In the below-described embodiments, a new RPS that delivers a much higher concentration of desired radical species is used as a radical species source for either processing a workpiece in a process chamber or for cleaning the chamber itself. Processes may include etch processing or chemical vapor deposition processing, for example. The new RPS consists of an array of low cost microwave magnetron heads coupled to conical, horn or other microwave emitter antennas above the gas shower head. A plasma is formed in a plasma generation zone between the microwave emitter antennas and the gas shower head. Radical species in the plasma diffuse through the shower head into a zone of the chamber containing the workpiece support stage. Ions in general do not diffuse through the gas shower head. The array of microwave magnetron heads delivers microwave power through localized dielectric windows to generate a plasma in the plasma generation zone, the plasma having a high concentration of radical species, in an extremely wide range of chamber pressures including an extremely low minimum pressure. The radical generation efficiency is increased significantly by reducing recombination losses, which increases productivity. These recombination losses are reduced because the radical species are produced in the processing chamber, not in a separate chamber. These recombination losses are further reduced because the minimum chamber pressure is far below minimum pressures required in conventional RPS systems.

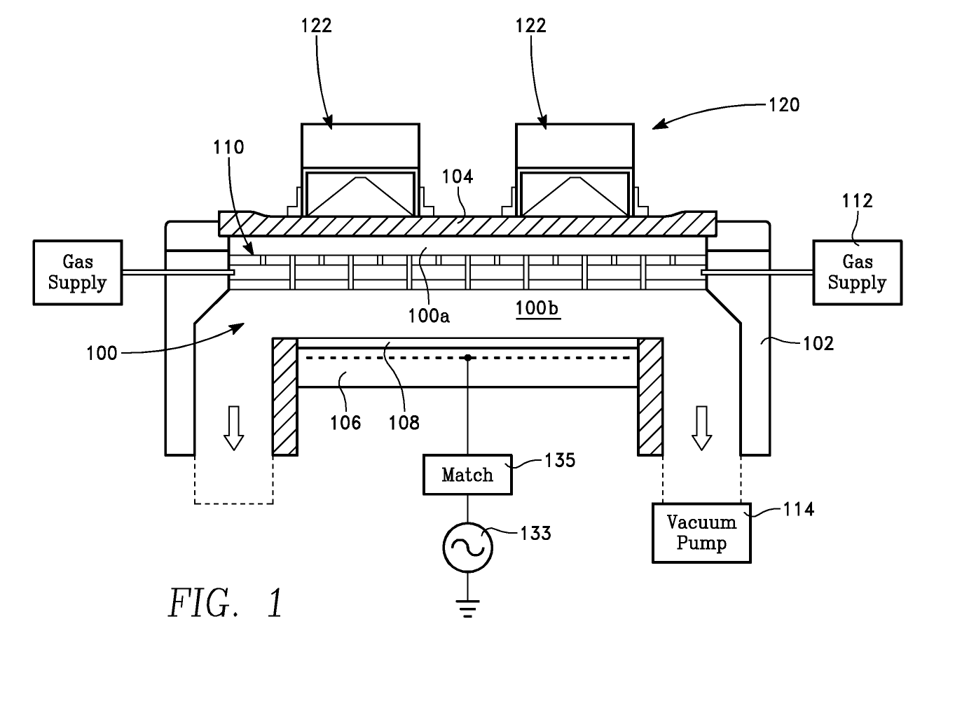

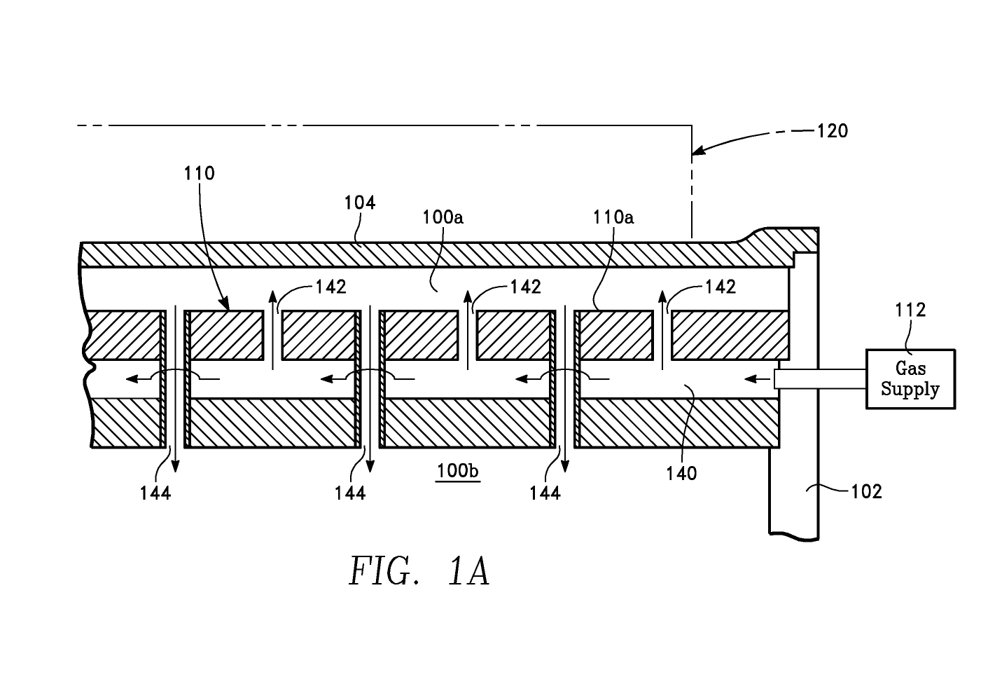

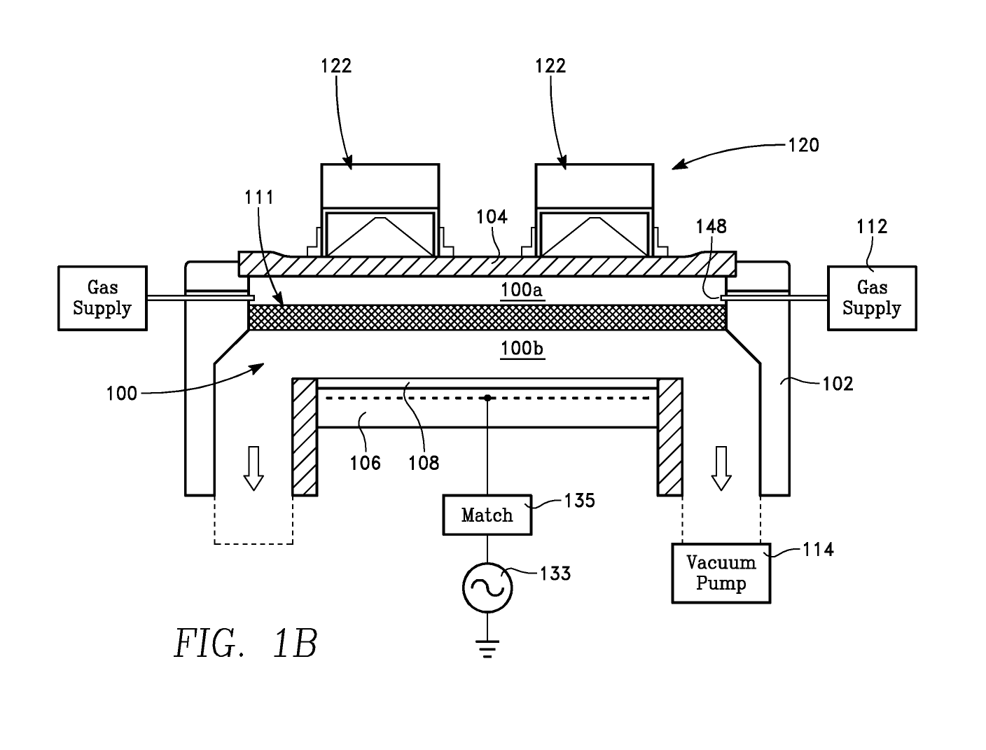

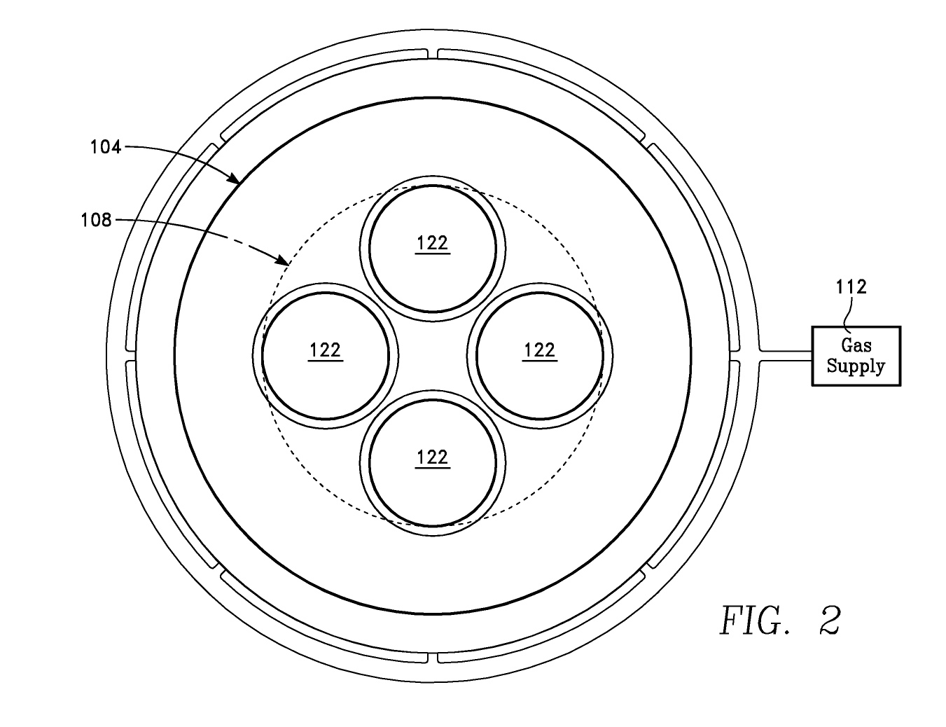

Referring to FIGS. 1 and 2, a plasma reactor has a chamber 100 enclosed by a side wall 102 and a ceiling 104. In a first embodiment, the ceiling 104 is a disk-shaped dielectric plate providing a vacuum seal. A workpiece support stage 106 faces the ceiling 104 and can support a workpiece 108 to be processed. In some modes of operation, the interior surfaces of the chamber 100 are cleaned, in which case the workpiece 108 is absent. A gas shower head 110 is supported beneath the ceiling 104 and over the workpiece support stage 106, and faces the workpiece support stage 106. The gas shower head 110 may be formed of a metal. A gas supply 112 is connected to the gas shower head 110. The gas supply 112 may provide a process gas that is a precursor for different species including a desired radical species, upon dissociation. A vacuum pump 114 evacuates the chamber 100 at a gas pumping rate that affects or controls the gas pressure within the chamber 100.

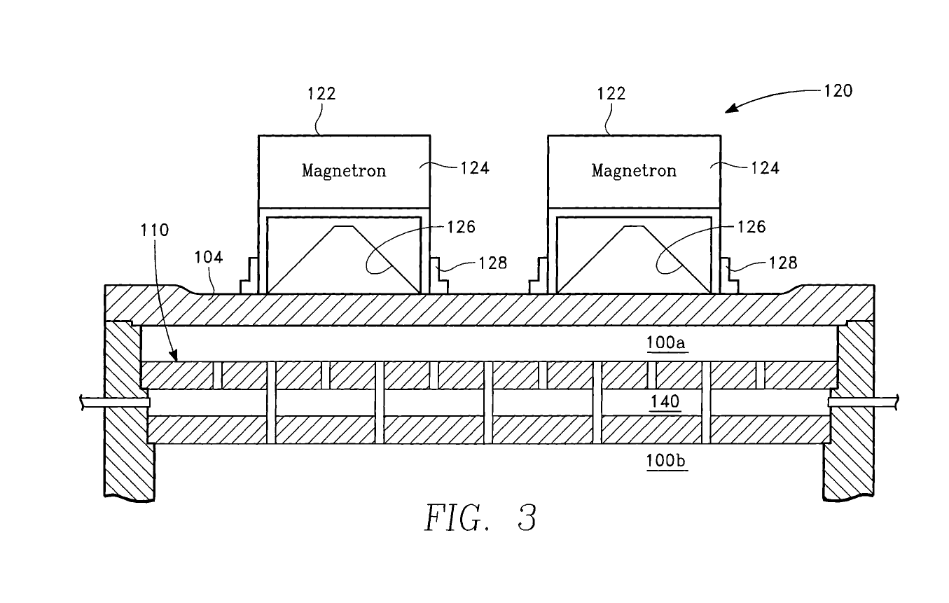

An array 120 of microwave sources 122 (microwave emitters) is supported on the ceiling 104. Referring to FIG. 3, each individual microwave source 122 includes a conventional magnetron 124 and a conical shaped antenna 126. The conical shaped antenna 126 defines a hollow cone whose apex faces or is coupled to the magnetron 124, the cone having a circular base resting on the ceiling 104. In the illustrated embodiments, each conical shaped antenna 126 has an axis of symmetry parallel with the axis of symmetry of the ceiling 104. The microwave source 122 may be fastened to an annular flange 128 for mounting on top of the ceiling 104. The ceiling 104, if formed of as a dielectric plate, is of sufficient thickness to withstand the pressure difference between the interior of the chamber 100 and atmospheric pressure.

The chamber 100 has a plasma generation zone 100a defined between the ceiling 104 and the gas shower head 110. The chamber 100 further has workpiece process zone 100b defined between the workpiece support stage 106 and the gas shower head 110. The gas showerhead 110 delivers process gases from the gas supply 112 into the plasma generation zone 100a. Power from the array 120 of microwave sources 122 excites the process gas to produce a plasma in the plasma generation zone 100a. This plasma contains the desired radical species. The direction of flow of raw or unexcited process gas from the gas shower head 110 into the plasma generation zone 100a is in the upward direction in the view of FIG. 1. The gas shower head 110 further functions as a grate or finely slotted baffle that blocks plasma ions but passively admits a downward flow of neutral or radical species from the plasma generation zone 100a into the workpiece process zone 100b. The microwave power is completely absorbed in the plasma generation zone 100a.

An advantage is that the plasma generation zone 100a and the workpiece process zone 100b are both within the same chamber (the chamber 100). This minimizes or nearly eliminates losses of radical species through recombination inherent in a conventional reactor chamber connected to a separate RPS chamber via a delivery tube.

In one embodiment, the gas shower head 110 may be implemented in the manner depicted in FIG. 1A. The gas shower head 110 in the embodiment of FIG. 1A has an internal gas manifold 140 connected to the gas supply 112, and an array of gas injection passages 142 extending upwardly from the internal gas manifold to a top surface 110a of the gas shower head 110. The gas injection passages 142 are open to the plasma generation zone 100a for injecting process gas into the plasma generation zone 100a. The gas shower head 110 of FIG. 1A further has an array of plasma by-product flow passages 144 formed as narrow slots or orifices extending through the gas shower head 110. The plasma by-product flow passages 144 provide downward flow paths from the plasma generation zone 100a to the workpiece process zone 100b for plasma by-products such as radical species produced in the plasma generation zone 100a. The plasma by-product flow passages 144 are sufficiently narrow to block downward flow of plasma ions from the plasma generation zone 100a.

In another embodiment depicted in FIG. 1B, gas injectors 148 in the side wall 102 face the plasma generation zone 100a and inject process gas from the gas supply 112 into the plasma generation zone 100a. In this embodiment, the gas shower head 110 may be replaced by a baffle 111 formed as a mesh, grate or a slotted barrier with an array of openings sufficiently narrow to block flow of plasma ions but sufficiently large to admit flow of radical species. The mesh 111 may be formed of a metal. The portion of each gas injector 148 that is exposed to the environment of the plasma generation zone 100a may be formed of a dielectric material to prevent interference with microwave power from the microwave sources 122.

In one embodiment, an optional RF bias power generator 133 is coupled to the workpiece support stage 106 through an optional impedance match 135.

As shown in FIG. 2, each of the microwave sources 122 occupies a circular zone of the ceiling 104 that is sufficiently small so that the entire array 120 of microwave sources 122 fits within the circumference of the ceiling 104. As shown in FIG. 2, the plural microwave sources 122 may be spaced apart from one another at uniform intervals. In the illustrated embodiments, the ceiling 104 is planar and the plural microwave sources 122 are attached to the ceiling 104 and arrayed in a plane.

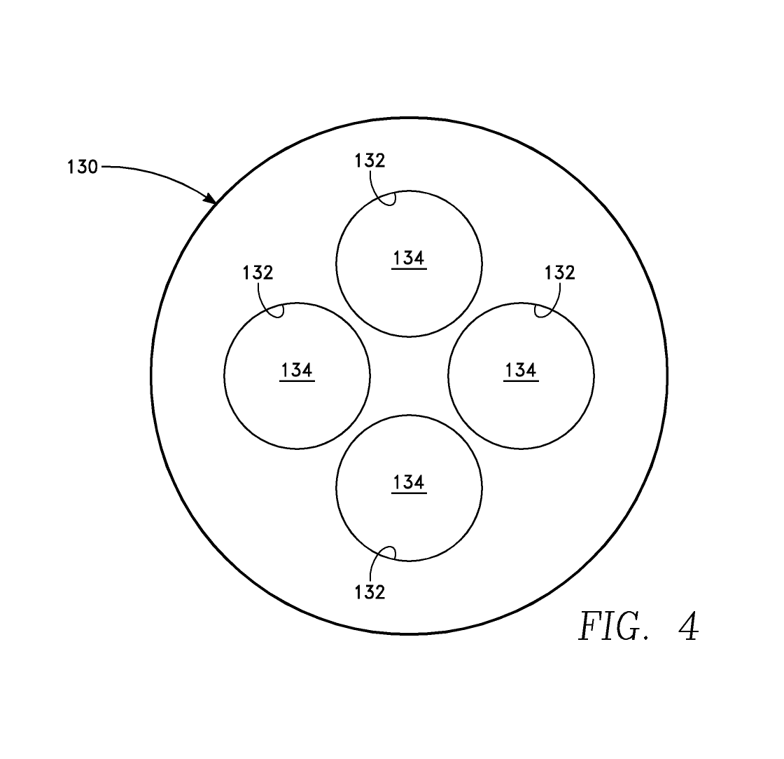

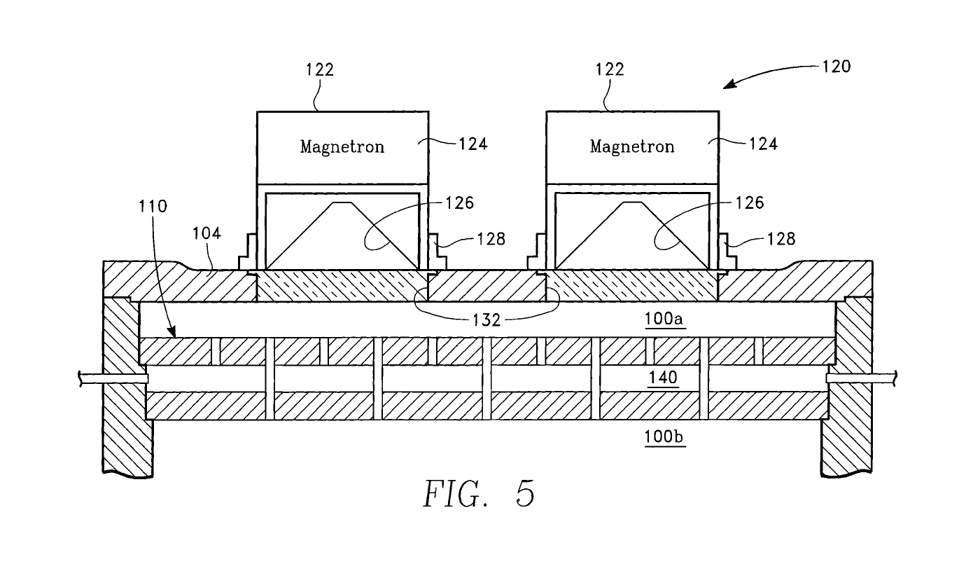

In an alternative embodiment depicted in FIGS. 4 and 5, the ceiling 104 is formed as a metal plate 130 having an array of circular ports 132 aligned with the array 120 of microwave sources 122. A dielectric window 134 is mounted in each circular port 132 and provides a vacuum seal. In the embodiment of FIGS. 4 and 5, there are four individual dielectric windows 134 aligned with respective ones of the microwave sources 122.

### Advantages

A conventional reactor employing a remote plasma source (RPS) typically has a main chamber for processing a workpiece and a separate RPS chamber in which a remote plasma is generated. Radical species are drawn from the remote plasma and travel through a delivery tube from the separate RPS chamber to the main chamber. Significant losses of radical species occur due to recombination during transit along the length of the delivery tube. In the embodiments of FIGS. 1-5, the RPS chamber is not separate but rather is integrated in the main chamber. This eliminates the delivery tube and separate chamber, thus dramatically reducing recombination losses of radical species with a corresponding increase in the population of radical species delivered into the main chamber.

Another advantage is that the microwave source can produce a high plasma ion density across an extremely wide range of chamber pressures (e.g., 0.5 Torr to 10 Torr). One of the reasons for this is the high frequency of a microwave source (e.g., 2.45 GHz). In contrast, RPS chambers employing inexpensive plasma sources (e.g., inductively coupled plasma sources, or capacitively coupled plasma sources, for example) are confined to a relatively high range of chamber pressures (e.g., 2 Torr to 6 Torr). (A microwave RPS is not practical in many cases because of its high cost, e.g., on the order of tens of thousands of dollars.) The high chamber pressures (required by non-microwave sources) increase recombination losses of radical species and limit the ion density of the plasma in the RPS chamber. In the described embodiments, the cost of a microwave plasma source is radically reduced by employing an overhead array of extremely low cost microwave emitters, as depicted in FIG. 1. Such emitters may be of the type employed in consumer microwave ovens (some costing less than $40 each), for example, and typically each provides about 1.5 kW output power.

The reduction of recombination losses of radical species together with the higher plasma density achieved with a microwave source results in a yield of radical species of as much as four or more times that of conventional RPS systems. The above-described embodiments are useful in performing various plasma processes on a workpiece, including etch processes and chemical vapor deposition processes, in addition to chamber cleaning processes.

While the foregoing is directed to embodiments of the present invention, other and further embodiments of the invention may be devised without departing from the basic scope thereof, and the scope thereof is determined by the claims that follow.

1. A plasma reactor, comprising:
a chamber comprising a side wall and a ceiling, and a workpiece support stage within said chamber;
an array of plural microwave sources mounted on said ceiling;
an ion-blocking baffle between said ceiling and said workpiece support stage and defining: (a) an upper chamber portion comprising a plasma generation zone between said ceiling and said ion-blocking baffle and (b) a lower chamber portion comprising a workpiece processing zone between said workpiece support stage and said ion-blocking baffle; and
said ion blocking baffle comprising:
an internal gas manifold extending parallel to top and bottom faces of said ion blocking baffle, said internal gas manifold adapted for connection to a supply of un-ionized gas;
an array of gas injection passages extending upwardly from said internal gas manifold to said plasma generation zone and distributed across a diameter of said ion blocking baffle, said array of gas injection passages for upward flow of un-ionized gas, said plasma generation zone for production of plasma by-products; and
an array of plasma by-product flow passages extending downwardly through said ion blocking baffle from said plasma generation zone to said workpiece processing zone, said array of plasma by-product flow passages for downward flow of plasma by-products.

2. The plasma reactor of claim 1 wherein each one of said microwave sources comprises a magnetron and a conical radiator antenna, each said conical radiator antenna having a cone apex facing said magnetron and a cone base facing an external surface of said ceiling.

3. The plasma reactor of claim 2 wherein said ceiling comprises a dielectric material.

4. The plasma reactor of claim 3 wherein said ceiling comprises a disk-shaped dielectric plate.

5. The plasma reactor of claim 3 wherein said ceiling comprises a metal plate, said metal plate comprising an array of plural openings extending through said metal plate in registration with respective ones of said plural microwave sources, and dielectric windows within said plural openings.

6. The plasma reactor of claim 5 wherein each of said plural openings is circular with a diameter corresponding to a diameter of a respective conical base of said conical radiator antenna.

7. (canceled)

8. The plasma reactor of claim 1 wherein said gas distributor comprises gas injection ports in said side wall adjacent said upper chamber portion.

9. The plasma reactor of claim 1 wherein each of said microwave sources occupies a zone of said ceiling that is sufficiently small that said array of microwave sources fits within a circumference of said ceiling.

10. The plasma reactor of claim 1 wherein said plural microwave sources are spaced apart from one another at uniform intervals.

11. The plasma reactor of claim 1 wherein said ceiling is planar and said plural microwave sources are attached to said ceiling and are arrayed in a plane.

12. The plasma reactor of claim 2 wherein each said conical radiator antenna has an axis of symmetry parallel with an axis of symmetry of said ceiling.

13. The plasma reactor of claim 1 wherein each of said plasma by-product flow passages being sufficiently narrow to limit or prevent propagation of plasma ions through said plasma by-product flow passages.

14. The plasma reactor of claim 13 wherein said plasma by-product flow passages are sufficiently wide to permit diffusion of neutral radical species through said ion-blocking baffle.

15. The plasma reactor of claim 13 wherein said ion-blocking baffle comprises metal.

16. The plasma reactor of claim 1 further comprising a vacuum pump coupled to said lower chamber portion.

17. The plasma reactor of claim 1 wherein said process gas supply contains gas comprising a precursor of a desired radical species.

18. A method of treating with radical species either a surface of a workpiece in a process chamber or an internal surface of the process chamber, comprising:
forming a ceiling of the process chamber of a material comprising a dielectric material;
dividing the process chamber into an upper portion and a lower portion;
mounting an array of plural microwave sources on an external side of said ceiling;
injecting a process gas into said upper portion; and
generating a plasma in said upper portion by radiating microwave power from said array of plural microwave sources into said upper portion of said process chamber, while preventing plasma ions from passing into said lower portion, and while allowing radical species to flow from said upper portion into said lower portion.

19. The method of claim 18 wherein said microwave power is of a frequency of 2.45 GHz.

20. The method of claim 18 further comprising maintaining a pressure of less than 2 Torr in said process chamber.
